(19) United States
(12) Patent Application Publication
(10) Pub. No.: US 2025/0311571 A1
(43) Pub. Date: Oct. 2, 2025

(54) DISPLAY APPARATUS

(71) Applicant: LG Display Co., Ltd., Seoul (KR)

(72) Inventor: Soohyun PARK, Gumi-si (KR)

(73) Assignee: LG Display Co., Ltd., Seoul (KR)

(21) Appl. No.: 19/059,818

(22) Filed: Feb. 21, 2025

(30) Foreign Application Priority Data
Mar. 26, 2024 (KR) 10-2024-0041165

(51) Int. Cl. H10K 59/131; H05K 1/18; H10K 59/80

(52) U.S. Cl. CPC H10K 59/131; H05K 1/189; H10K 59/871; H05K 2201/10128

(57) ABSTRACT

A display apparatus includes a display panel including a display area and a non-display area adjacent to the display area. The display apparatus includes a pad area disposed in the non-display area of the display panel. The pad area includes pads electrically connected to the display area. The display apparatus includes one or more flexible circuit boards coupled or electrically connected to the pad area. The display apparatus includes a reinforcing member overlapping the pad area and a portion of the flexible circuit board. The reinforcing member protrudes more than both ends of the display panel.

### CROSS REFERENCE TO RELATED APPLICATION

The present application claims priority to Korean Patent Application No. 10-2024-0041165, filed Mar. 26, 2024, the entire contents of which is incorporated herein for all purposes by this reference.

### BACKGROUND

### Technical Field

The present specification relates to a display apparatus.

### Description of the Related Art

In the full-fledged information age, the field of display apparatuses for visually displaying electrical information signals is developing rapidly, and research for developing performance, such as thinness, lightweight, and lower power consumption, for any display apparatus is being continuously conducted.

Exemplary display apparatuses may include liquid crystal displays (LCDs), electro-wetting displays (EWDs), organic light emitting displays (OLEDs), etc.

Among them, organic light emitting displays are self-luminous display apparatuses and unlike the LCD, do not require a separate light source, and thus lightweight and thin displays may be manufactured. In addition, the organic light emitting displays are advantageous in terms of power consumption due to a low-voltage operation and also have excellent color expression, response speed, viewing angle, and contrast ratio (CR), and thus are expected to be used in any field.

### BRIEF SUMMARY

One or more embodiments of the present specification is directed to providing a display apparatus that is capable of applying a reinforcing member to a pad area of a display panel, thereby preventing an external impact.

One or more embodiments of the present specification is also directed to providing a display apparatus that is capable of applying a reinforcing member to a pad area of a display panel, thereby reducing a change in shrinkage and expansion of a display panel in a high-temperature and high-humidity environment.

The technical benefits of embodiments of the present specification are not limited to the above-described benefits, and other benefits that are not mentioned will be able to be clearly understood by those skilled in the art from the following description.

A display apparatus according to one embodiment of the present specification includes a display panel including a display area and a non-display area outside the display area, a pad area disposed in the non-display area of the display panel and including pads electrically connected to the display area, one or more flexible circuit boards connected to the pad area, and a reinforcing member overlapping the pad area and a portion of the flexible circuit board, wherein the reinforcing member protrudes more than both ends of the display panel. In addition, a display apparatus according to another embodiment of the present specification includes a display panel including a display area and a non-display area outside the display area, a pad area disposed in the non-display area of the display panel and including pads electrically connected to the display area, and a reinforcing member at least partially covering the pad area.

Detailed matters of other embodiments are included in a detailed description and accompanying drawings.

### BRIEF DESCRIPTION OF THE SEVERA1 VIEWS OF THE DRAWINGS

FIG. 1 is a block diagram of a display apparatus according to one embodiment of the present specification.

FIG. 2 is a circuit diagram of a sub-pixel of the display apparatus according to one embodiment of the present specification.

FIG. 3 is a cross-sectional view of a sub-pixel disposed in a display area of a display panel of the display apparatus according to the embodiment of the present specification.

FIG. 4 is a plan view of a portion of the display panel according to one embodiment of the present specification.

FIG. 5 is a plan view of the display panel according to one embodiment of the present specification.

FIG. 6 is a cross-sectional view along line I-I′ in FIG. 5.

FIG. 7 is an enlarged view of a reinforcing member of the present specification.

FIG. 8 is an enlarged view of area A in FIG. 5.

### DETAILED DESCRIPTION

Advantages and features of the present specification and methods for achieving them will become clear with reference to embodiments described below in detail in conjunction with the accompanying drawings. However, the present specification is not limited to embodiments disclosed below but will be implemented in various different forms, these embodiments are merely provided to make the disclosure of the present specification complete and fully inform those skilled in the art to which the present specification pertains of the scope of the present specification.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In describing one embodiment of the present specification, when it is determined that the detailed description of a related known technology may unnecessarily obscure the gist of embodiment of the present specification, detailed description thereof will be omitted.

When terms “comprises,” “has,” “consists of,” and the like described in the present specification are used, other parts may be added unless “only” is used. When a component is expressed in the singular, it includes a case in which the component is provided as a plurality of components unless specifically stated otherwise.

In construing a component, the component is construed as including the margin of error even when there is no separate explicit description.

When the positional relationship is described, for example, when the positional relationship between two parts is described using the term “on,” “above,” “under,” “next to,” or the like, one or more other parts may be positioned between the two parts unless the term “immediately” or “directly” is used.

When an element or a layer is described as being disposed “on” another element or layer, it includes both a case in which the element or the layer is disposed directly on another element or layer and a case in which other layers or elements are interposed therebetween.

In addition, when described as ‘coupled’ or ‘connected,’ it may include a case of being ‘coupled’ or ‘connected’ through one or more other components positioned between two components unless “immediately” or ‘directly’ is used.

Although first, second, etc., are used to describe various components, it goes without saying that these components are not limited by these terms. These terms are only used to distinguish one component from another component. Therefore, it goes without saying that a first component to be described below may be a second component within the technical spirit of the present specification.

The same reference numeral denotes the same component throughout the present specification.

The area and thickness of each component shown in the drawings are shown as one example, and the embodiments of the present specification are not necessarily limited to the areas and thicknesses of the shown components.

Features of various embodiments of the present specification can be coupled or combined partially or entirely, and various technological interworking and driving are possible, and the embodiments may be implemented independently of each other or implemented together in an associated relationship.

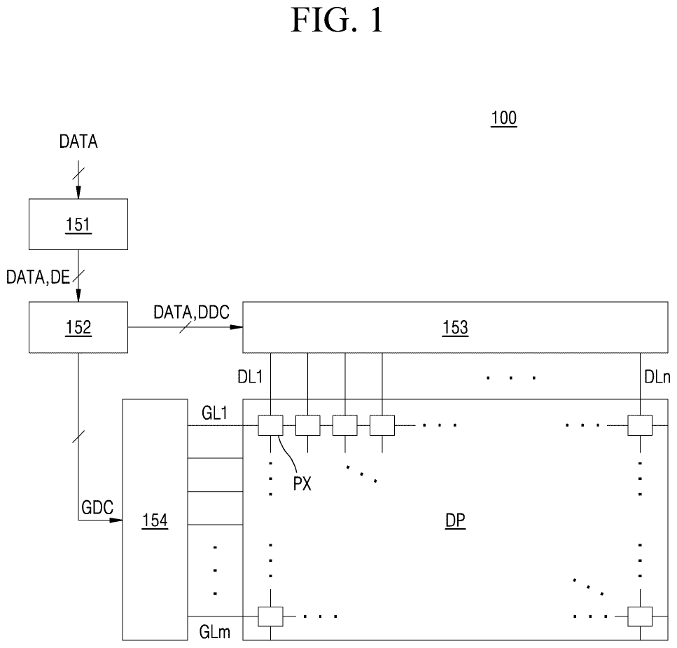

FIG. 1 is a block diagram of a display apparatus according to one embodiment of the present specification.

Referring to FIG. 1, a display apparatus 100 according to one embodiment of the present specification may include an image processing unit 151, a timing controller 152, a data driver 153, a gate driver 154, and a display panel DP.

The image processing unit 151 outputs a data signal DATA and a driving signal including a data enable signal DE supplied from the outside. In addition to the data enable signal DE, the image processing unit 151 may output a driving signal including one or more of a vertical synchronization signal, a horizontal synchronization signal, and a clock signal.

The timing controller 152 receives the driving signal including the data enable signal DE, etc., and the data signal DATA from the image processing unit 151. The timing controller 152 outputs a gate timing control signal GDC for controlling the operation timing of the gate driver 154 based on the driving signal. The timing controller 152 outputs the data signal DATA supplied from the image processing unit 151 and a data timing control signal DDC for controlling the operation timing of the data driver 153.

The data driver 153 samples and latches the data signal DATA supplied from the timing controller 152 in response to the data timing control signal DDC supplied from the timing controller 152, converts the sampled and latched data signal DATA into a gamma reference voltage, and outputs the gamma reference voltage. In addition, the data driver 153 outputs a data signal through data lines DL1 to DLn.

The gate driver 154 outputs a gate signal in response to the gate timing control signal GDC supplied from the timing controller 152 and at this time, may output the gate signal by shifting the level of the gate voltage. In addition, the gate driver 154 outputs the gate signal through gate lines GL1 to GLm.

The display panel DP includes a plurality of pixels PX, and the plurality of pixels PX display an image by emitting light in response to the data signal and gate signal supplied from the data driver 153 and the gate driver 154, respectively.

One pixel PX may be formed of a plurality of sub-pixels. For example, one pixel PX may include three or more sub-pixels that emit light of different colors. For example, in the display apparatus 100 according to one embodiment of the present specification, one pixel PX may include sub-pixels that emit light of red, green, and blue. However, the number of sub-pixels included in one pixel PX is not limited, and for example, in addition to the sub-pixels that emit light of red, green, and blue, a sub-pixel that emits light of white may be further included.

On the display panel DP, the plurality of gate lines GL1 to GLm extending in a first direction and the plurality of data lines DL1 to DLn extending in a second direction different from the first direction are arranged to intersect each other. A pixel PX is defined at each point at which the plurality of gate lines and data lines intersect on the display panel DP.

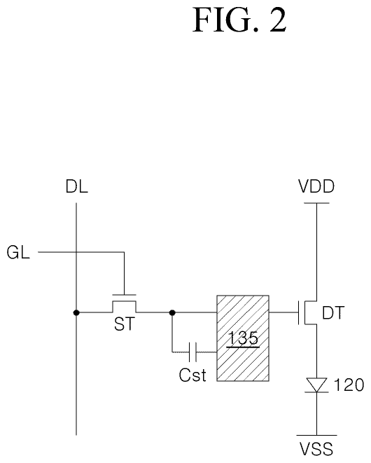

FIG. 2 is a circuit diagram of a sub-pixel of the display apparatus according to one embodiment of the present specification.

The sub-pixel of the display apparatus according to one embodiment of the present specification may include a light emitting element 120 and a driving circuit. Referring to FIG. 2, the driving circuit of the sub-pixel according to one embodiment of the present specification may include a driving transistor DT, a switching transistor ST, a capacitor Cst, a gate line GL, a data line DL, lines connected to high-potential and low-potential power sources VDD and VSS for driving a pixel, etc.

The light emitting element 120 may operate to emit light according to a driving current generated by the driving transistor DT. The switching transistor ST may perform a switching operation so that the data signal supplied through the data line DL is stored as a data voltage in the capacitor Cst in response to the gate signal supplied through the gate line GL. The driving transistor DT may operate so that a constant driving current flows between the high-potential power source VDD and the low-potential power source VSS in response to the data voltage stored in the capacitor Cst.

In addition, the sub-pixel may further include a compensation circuit 135.

The compensation circuit 135 is a circuit for compensating for a threshold voltage of the driving transistor DT, etc., and the compensation circuit 135 may include one or more thin film transistors and capacitors. In this case, the configuration and structure of the thin film transistor for compensation and the capacitor for compensation are not limited and may vary depending on a compensation method. For example, when the compensation circuit 135 is added to the sub-pixel, the compensation circuit 135 may have various structures such as 3T1C, 4T2C, 5T2C, 6T1C, 6T2C, 7T1C, and 7T2C.

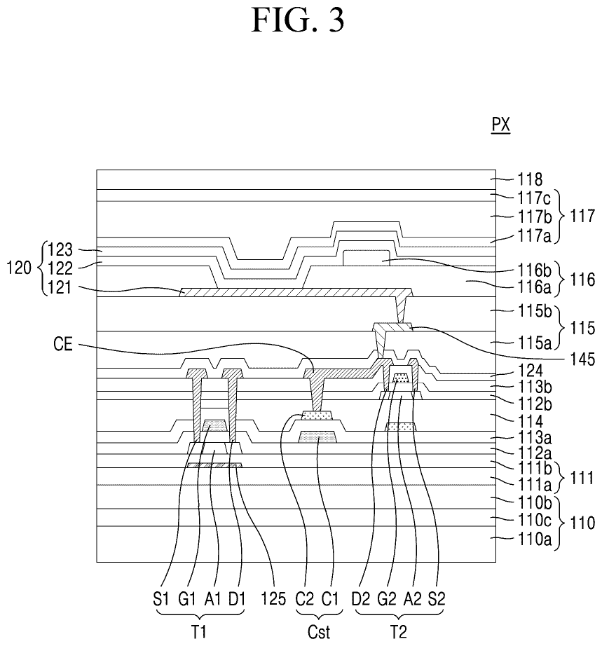

A structure of the pixel PX disposed in the display area of the display panel will be described in more detail with reference to FIG. 3. FIG. 3 shows an example of a stacked structure for one sub-pixel constituting the pixel PX.

Referring to FIG. 3, the display apparatus 100 according to one embodiment of the present specification may include the substrate 110, a first buffer layer 111, a metal layer 125, a first thin film transistor T1, a first gate insulating layer 112a, a first interlayer insulating layer 113a, a second buffer layer 114, a second thin film transistor T2, a second gate insulating layer 112b, a second interlayer insulating layer 113b, a connection electrode CE, a planarization layer 115, an auxiliary electrode 145, a bank part 116, a light emitting element 120, and an encapsulation part 117.

The substrate 110 serves to support and protect components of the display apparatus disposed thereon.

For example, when the substrate 110 is made of polyimide (PI), moisture may penetrate the substrate 110 made of polyimide (PI) and penetrate to the thin film transistor or the light emitting element, thereby degrading the performance of the display apparatus 100. To prevent a degradation in performance of the display apparatus 100 due to such moisture penetration, the display apparatus 100 according to one embodiment of the present specification may adopt a double polyimide (PI) structure as the substrate 110.

For example, as shown in FIG. 3, the substrate 110 may include a first substrate 110a and a second substrate 110b each made of polyimide (PI), and an inorganic insulating layer 110c formed between the first substrate 110a and the second substrate 110b.

The inorganic insulating layer 110c may be formed of a single layer or multiple layers of silicon nitride (SiNₓ) or silicon oxide (SiOₓ). For example, the inorganic insulating layer 110c may be made of silicon dioxide (SiO₂), but is not limited thereto, and may be formed of a double layer of silicon dioxide (SiO₂) and silicon nitride (SiNₓ).

The inorganic insulating layer 110c blocks moisture from penetrating into an upper portion of the second substrate 110b. In addition, when a charge is charged to the first substrate 110a, the inorganic insulating layer 110c can block the charged charge from affecting the first thin film transistor T1 through the second substrate 110b. In this way, it is possible to block the charge charged to the lower polyimide (PI) by the inorganic insulating layer 110c, thereby improving the reliability of the product, and omit the process of arranging a separate metal layer for blocking a charge, thereby simplifying the process and reducing the manufacturing cost.

A first buffer layer 111 is disposed on the substrate 110.

For example, as shown in FIG. 3, the first buffer layer 111 may include a multi-buffer layer 111a and an active buffer layer 111b, the multi-buffer layer 111a may be disposed on the substrate 110, and the active buffer layer 111b may be disposed on the multi-buffer layer 111a.

The metal layer 125 may be disposed between the multi-buffer layer 111a and the active buffer layer 111b. That is, the metal layer 125 is disposed on the multi-buffer layer 111a, and the active buffer layer 111b is disposed on the metal layer 125. The metal layer 125 may serve as a light shield and may be referred to as a light shielding layer.

The first thin film transistor T1 is disposed on the first buffer layer 111.

The first thin film transistor T1 includes a first active layer A1, a first gate electrode G1, a first source electrode S1, and a first drain electrode D1. However, according to the design of the pixel circuit, the first source electrode S1 may be the first drain electrode, and the first drain electrode D1 may be the first source electrode.

The first active layer A1 is disposed on the first buffer layer 111. The first active layer A1 may contain amorphous silicon or polycrystalline silicon. For example, the first active layer A1 may contain low temperature poly silicon (LTPS). Since the poly silicon material has high mobility (100 cm²/Vs or more), low energy consumption, and excellent reliability, the poly silicon material may be applied to a gate driver and/or a multiplexer (MUX) for a driving element that drive thin film transistors for a display element. In the display apparatus 100 according to one embodiment of the present specification, low temperature poly silicon (LTPS) is applied to the active layer A1 of the first thin film transistor T1, but the low temperature poly silicon (LTPS) may be applied to the active layer A2 of the second thin film transistor T2 depending on the characteristics of the display apparatus 100. In addition, in the display apparatus 100 according to one embodiment of the present specification, the first active layer A1 to which the low temperature poly silicon (LTPS) is applied may be used as the active layer of the driving transistor, but is not limited thereto. For example, according to the characteristics of the display apparatus 100, the low temperature poly silicon (LTPS) may be applied to an active layer of the switching transistor.

The first active layer A1 may include a first channel area in which a channel is formed when the first thin film transistor T1 is driven, and a first source area and a first drain area at both sides of the first channel area. The first source area of the first active layer A1 is connected to the first source electrode S1, and the first drain area is connected to the first drain electrode D1. For example, the first source area and the first drain area may be formed by ion doping (impurity doping) of the first active layer A1. The first source area and the first drain area may be formed by ion doping into the polysilicon material, and the first channel area may be a portion in which the polysilicon material remains without being ion doped.

The first gate insulating layer 112a is disposed on the first active layer A1.

The first gate insulating layer 112a may be disposed on the entire substrate 110 including the first active layer A1. For example, the first gate insulating layer 112a may be formed of a single layer or multiple layers of silicon nitride (SiNₓ) or silicon oxide (SiOₓ). A contact hole may be formed in the first gate insulating layer 112a so that the first source electrode S1 and the first drain electrode D1 of the first thin film transistor T1 are connected to the first source area and the first drain area of the first active layer A1 of the first thin film transistor T1, respectively.

The first gate electrode G1 of the first thin film transistor T1 and a first capacitor electrode C1 of the storage capacitor Cst are disposed on the first gate insulating layer 112a.

The first gate electrode G1 and the first capacitor electrode C1 may be formed of a single layer or multiple layers made of one of molybdenum (Mo), copper (Cu), titanium (Ti), aluminum (Al), chromium (Cr), gold (Au), nickel (Ni), and neodymium (Nd) or an alloy thereof.

The first gate electrode G1 may be formed on the first gate insulating layer 112a to overlap the first channel area of the first active layer A1 of the first thin film transistor T1.

The first capacitor electrode C1 may be omitted based on the driving characteristics of the display apparatus 100, the structure and type of the thin film transistor, etc. The first gate electrode G1 and the first capacitor electrode C1 may be made of the same material and formed on the same layer. That is, the first gate electrode G1 and the first capacitor electrode C1 may be formed by the same process.

The first interlayer insulating layer 113a is disposed on the first gate insulating layer 112a, the first gate electrode G1, and the first capacitor electrode CL.

The first interlayer insulating layer 113a may be formed of a single layer or multiple layers of silicon nitride (SiNₓ) or silicon oxide (SiOₓ). In addition, a contact hole may be formed in the first interlayer insulating layer 113a to expose the first source area and the first drain area of the first active layer A1 of the first thin film transistor T1.

A second capacitor electrode C2 of the storage capacitor Cst is disposed on the first interlayer insulating layer 113a.

The second capacitor electrode C2 may be formed of a single layer or multiple layers made of one of molybdenum (Mo), copper (Cu), titanium (T1), aluminum (Al), chromium (Cr), gold (Au), nickel (Ni), and neodymium (Nd), or an alloy thereof. The second capacitor electrode C2 may be formed on the first interlayer insulating layer 113a to overlap the first capacitor electrode CL. In addition, the second capacitor electrode C2 may be made of the same material as the first capacitor electrode C1. The second capacitor electrode C2 may be omitted based on the driving characteristics of the display apparatus 100, the structure and type of the thin film transistor, etc.

The second buffer layer 114 is disposed on the first interlayer insulating layer 113a and the second capacitor electrode C2.

The second buffer layer 114 may be formed of a single layer or multiple layers of silicon nitride (SiNₓ) or silicon oxide (SiOₓ). A contact hole may be formed in the second buffer layer 114 to expose the first source area and the first drain area of the first active layer A1 of the first thin film transistor T1. In addition, a contact hole may be formed in the second buffer layer 114 to expose the second capacitor electrode C2 of the storage capacitor Cst.

The second thin film transistor T2 is disposed on the second buffer layer 114.

The second thin film transistor T2 includes a second active layer A2, a second gate electrode G2, a second source electrode S2, and a second drain electrode D2. However, according to the design of the pixel circuit, the second source electrode S2 may be the second drain electrode, and the second drain electrode D2 may be the second source electrode.

The second active layer A2 is disposed on the second buffer layer 114. The second active layer A2 may be made of an oxide semiconductor. Since the oxide semiconductor material has a larger band gap than the silicon material, electrons may not cross the band gap in an off state, and thus an off-current is low. Therefore, a thin film transistor including an active layer formed of an oxide semiconductor may be suitable for a switching transistor having a short on-time and a long off-time, but is not limited thereto. The thin film transistor including an active layer formed of an oxide semiconductor may be applied to a driving transistor according to the characteristics of the display apparatus 100. In addition, a thin film transistor including an active layer made of an oxide semiconductor is suitable for a high-resolution display element because it has a low off-current and thus a size of the auxiliary capacitance can be reduced. For example, the second active layer A2 is made of a metal oxide and may be made of any metal oxide such as indium-gallium-zinc-oxide (IGZO). Although one embodiment of the present specification has been described assuming that the second active layer A2 of the second thin film transistor T2 is made of IGZO among various metal oxides, the present specification is not limited thereto, and the second active layer A2 may be made of another metal oxide such as indium-zinc-oxide (IZO), indium-gallium-tin-oxide (IGTO), or indium-gallium-oxide (IGO) rather than IGZO. The second active layer A2 may be formed by depositing a metal oxide on the second buffer layer 114, performing a heat treatment process for stabilization, and then patterning the metal oxide.

The second active layer A2 may include a second channel area in which a channel is formed when the second thin film transistor T2 is driven, and a second source area and a second drain area at both sides of the second channel area. The second source area of the second active layer A2 is connected to the second source electrode S2, and the second drain area is connected to the second drain electrode D2.

In the display apparatus 100 according to one embodiment of the present specification, a light shielding layer that serves as a light shield may be disposed under the second thin film transistor T2. For example, as shown in FIG. 3, a metal layer having the same function as the metal layer 125 may be further disposed under the second buffer layer 114, and the metal layer may be disposed to overlap the second active layer A2 on the first interlayer insulating layer 113a.

The second gate insulating layer 112b is disposed on the second active layer A2.

The second gate insulating layer 112b may be disposed on the entire substrate 110 including the second active layer A2. For example, the second gate insulating layer 112b may be formed of a single layer or multiple layers of silicon nitride (SiNₓ) or silicon oxide (SiOₓ).

The second gate electrode G2 may be disposed on the second gate insulating layer 112b.

The second gate electrode G2 may be formed of a single layer or multiple layers made of one of molybdenum (Mo), copper (Cu), titanium (T1), aluminum (Al), chromium (Cr), gold (Au), nickel (Ni), and neodymium (Nd), or an alloy thereof.

For example, the second gate electrode G2 is formed by forming a metal material on the second gate insulating layer 112b, forming a photoresist pattern on the metal material, and then wet-etching the metal material using the photoresist pattern as a mask. As a wet etchant for etching the metal material, a material that selectively etches molybdenum (Mo), copper (Cu), titanium (T1), aluminum (Al), chromium (Cr), gold (Au), nickel (Ni), and neodymium (Nd) that constitute the metal material or an alloy thereof and does not etch an insulating material may be used.

The second interlayer insulating layer 113b may be disposed on the second gate insulating layer 112b and the second gate electrode G2.

A contact hole may be formed in the second interlayer insulating layer 113b to expose the first active layer A1 of the first thin film transistor T1 and the second active layer A2 of the second thin film transistor T2. For example, a contact hole may be formed in the second interlayer insulating layer 113b to expose the first source area and the first drain area of the first active layer A1 in the first thin film transistor T1. In addition, a contact hole may be formed in the second interlayer insulating layer 113b to expose the second source area and the second drain area of the second active layer A2 of the second thin film transistor T2.

The second interlayer insulating layer 113b may be formed of a single layer or multiple layers of silicon nitride (SiNₓ) or silicon oxide (SiOₓ).

The connection electrode CE, the first source electrode S1 and the second drain electrode D1 of the first thin film transistor T1, and the second source electrode S2 and the second drain electrode D2 of the second thin film transistor T2 may be disposed on the second interlayer insulating layer 113b.

The connection electrode CE may be electrically connected to the second drain electrode D2 of the second thin film transistor T2. In addition, the connection electrode CE may be electrically connected to the second capacitor electrode C2 of the storage capacitor Cst through the contact hole formed in the second buffer layer 114, the second gate insulating layer 112b, and the second interlayer insulating layer 113b. That is, the connection electrode CE may serve to electrically connect the second capacitor electrode C2 of the storage capacitor Cst to the second drain electrode D2 of the second thin film transistor T2.

Here, the first source electrode S1 and the first drain electrode D1 of the first thin film transistor T1 may be connected to the first active layer A1 of the first thin film transistor T1 through the contact hole formed in each of the first gate insulating layer 112a, the first interlayer insulating layer 113a, the second buffer layer 114, the second gate insulating layer 112b, and the second interlayer insulating layer 113b.

In addition, the second source electrode S2 and the second drain electrode D2 of the second thin film transistor T2 may be connected to the second active layer A2 through the contact hole formed in the second gate insulating layer 112b and the second interlayer insulating layer 113b.

The connection electrode CE, the first source electrode S1 and the first drain electrode D1 of the first thin film transistor T1, and the second source electrode S2 and the second drain electrode D2 of the second thin film transistor T2 may be made of the same material by the same process.

For example, the connection electrode CE, the first source electrode S1 and the first drain electrode D1 of the first thin film transistor T1, and the second source electrode S2 and the second drain electrode D2 of the second thin film transistor T2 may be formed of a single layer or multiple layers made of one of molybdenum (Mo), copper (Cu), titanium (T1), aluminum (Al), chromium (Cr), gold (Au), nickel (Ni), neodymium (Nd), or an alloy thereof. For example, the connection electrode CE, the first source electrode S1 and the first drain electrode D1 of the first thin film transistor T1, and the second source electrode S2 and the second drain electrode D2 of the second thin film transistor T2 may be formed of a three-layer structure of titanium (T1)/aluminum (Al)/titanium (T1), but is not limited thereto.

The connection electrode CE may be integrally connected to the second drain electrode D2 of the second thin film transistor T2, but is not limited thereto.

An inorganic layer 124 is disposed on the connection electrode CE, the first source electrode S1 and the first drain electrode D1 of the first thin film transistor T1, the second source electrode S2 and the second drain electrode D2 of the second thin film transistor T2, and the second interlayer insulating layer 113b.

The inorganic layer 124 is a passivation layer for protecting the first thin film transistor T1 and the second thin film transistor T2 and may be formed of, for example, silicon oxide (SiOₓ), silicon nitride (SiNₓ), or multiple layers thereof.

A first planarization layer 115a of the planarization layer 115 is disposed on the inorganic layer 124.

The first planarization layer 115a may be an organic layer for planarizing and protecting upper portions of the first thin film transistor T1 and the second thin film transistor T2. For example, the first planarization layer 115a may be made of an organic material such as an acrylic resin, an epoxy resin, a phenolic resin, a polyamide resin, or a polyimide resin.

An auxiliary electrode 145 is disposed on the first planarization layer 115a.

The auxiliary electrode 145 may be connected to the second drain electrode D2 of the second thin film transistor T2 through the contact hole of the first planarization layer 115a. The auxiliary electrode 145 may serve to electrically connect the second thin film transistor T2 to the anode electrode 121. In addition, the auxiliary electrode 145 may be formed of a single layer or multiple layers made of one of molybdenum (Mo), copper (Cu), titanium (T1), aluminum (Al), chromium (Cr), gold (Au), nickel (Ni), and neodymium (Nd) or an alloy thereof. The auxiliary electrode 145 may be made of the same material as the second source electrode S2 and the second drain electrode D2 of the second thin film transistor T2.

A second planarization layer 115b of the planarization layer 115 is disposed on the auxiliary electrode 145 and the first planarization layer 115a.

For example, the second planarization layer 115b may be made of an organic material such as an acrylic resin, an epoxy resin, a phenolic resin, a polyamide resin, or a polyimide resin.

The light emitting element 120 is disposed on the second planarization layer 115b. The light emitting element 120 includes an anode electrode 121, a light emitting layer 122, and a cathode electrode 123.

In addition, a bank 116a of a bank part 116 is disposed on the second planarization layer 115b. The bank 116a may include an open area that exposes a portion corresponding to a light emitting area of each sub-pixel.

The anode electrode 121 of the light emitting element 120 is disposed on the second planarization layer 115b. The anode electrode 121 may be made of a metallic material and electrically connected to the auxiliary electrode 145 through the contact hole provided in the second planarization layer 115b. For example, when the display apparatus 100 according to one embodiment of the present specification is a top emission type, light emitted from the light emitting element 120 may be emitted upward from the substrate 110, and in this case, the anode electrode 121 may include a transparent conductive layer and a reflective layer on the transparent conductive layer. For example, the transparent conductive layer may be made of a transparent conductive oxide such as ITO or IZO, and the reflective layer may be made of silver (Ag), aluminum (Al), gold (Au), molybdenum (Mo), tungsten (W), chromium (Cr), or an alloy thereof.

The bank 116a may be disposed to cover both end portions of the anode electrode 121, and a portion of the anode electrode 121 may be exposed through an open area of the bank 116a. For example, the bank 116a may be made of an inorganic insulating material such as silicon nitride (SiNₓ), silicon oxide (SiOₓ), or an organic insulating material such as a benzocyclobutene-based resin, an acrylic-based resin, or an imide-based resin, but is not limited thereto. A spacer 116b of the bank part 116 may be further disposed on the bank 116a.

The light emitting layer 122 of the light emitting element 120 is disposed in the open area of the bank 116a and an area near the open area. Therefore, the light emitting layer 122 may be disposed on the anode electrode 121 exposed through the open area of the bank 116a. For example, the light emitting layer 122 may include a plurality of organic films. The cathode electrode 123 is disposed on the light emitting layer 122 of the light emitting element 120.

An encapsulation part 117 is disposed on the light emitting element 120.

The encapsulation part 117 may have a single-layer structure or a multilayered structure. For example, as shown in FIG. 3, the encapsulation part 117 may include a first encapsulation layer 117a, a second encapsulation layer 117b, and a third encapsulation layer 117c. In this case, the first encapsulation layer 117a and the third encapsulation layer 117c may be formed of an inorganic film, and the second encapsulation layer 117b may be formed of an organic film. Among the first encapsulation layer 117a, the second encapsulation layer 117b, and the third encapsulation layer 117c, the second encapsulation layer 117b is the thickest and may serve as a planarization layer.

The encapsulation part 117 may have the first encapsulation layer 117a disposed to be closest to the light emitting element 120. That is, the first encapsulation layer 117a may be disposed on the cathode electrode 123 of the light emitting element 120.

The first encapsulation layer 117a may be made of an inorganic insulating material capable of low-temperature deposition. For example, the first encapsulation layer 117a may be made of silicon nitride (SiNₓ), silicon oxide (SiOₓ), silicon oxynitride (SiON), aluminum oxide (Al₂O₃), etc. Since the first encapsulation layer 117a is deposited in a low-temperature atmosphere, it is possible to prevent damage to the light emitting layer 122 containing an organic material that is vulnerable to a high-temperature atmosphere during a deposition process.

The second encapsulation layer 117b may be formed to have a smaller area than the first encapsulation layer 117a. In this case, the second encapsulation layer 117b may be formed to expose both ends of the first encapsulation layer 117a. The second encapsulation layer 117b may serve as a buffer for reducing stress between the layers due to bending of the flexible display apparatus and serve to reinforce planarization performance. For example, the second encapsulation layer 117b may be made of an organic insulating material such as an acrylic resin, an epoxy resin, polyimide, polyethylene, or silicon oxycarbon (SiOC). For example, the second encapsulation layer 117b may be formed through an inkjet method, but is not limited thereto.

The third encapsulation layer 117c may be formed to cover an upper surface and side surfaces of each of the second encapsulation layer 117b and the first encapsulation layer 117a on the substrate 110 which the second encapsulation layer 117b is formed. In this case, the third encapsulation layer 117c can minimize or block external moisture or oxygen from penetrating into the first encapsulation layer 117a and the second encapsulation layer 117b. For example, the third encapsulation layer 117c may be made of silicon nitride (SiNₓ), silicon oxide (SiOₓ), silicon oxynitride (SiON), aluminum oxide (Al₂O₃), etc.

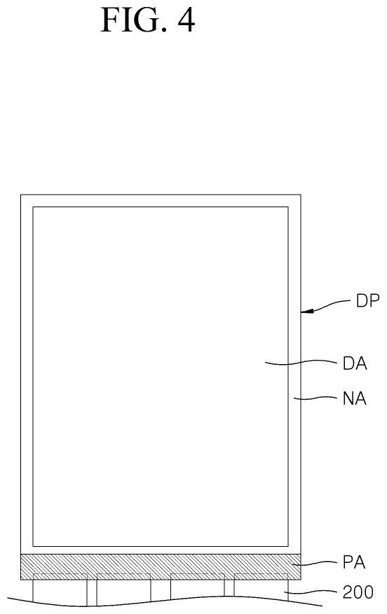

At least one blocking structure that blocks the flow of the second encapsulation layer 117b of the encapsulation part 117 may be disposed in a non-display area NA (see FIG. 4).

Meanwhile, in the display apparatus 100 according to one embodiment of the present specification, a color filter part, a touch detection part, etc., may be further disposed on the encapsulation part 117, but the present specification is not limited thereto.

For example, as shown in FIG. 3, a buffer film 118, which may be a touch buffer film for arranging the touch detection part, may be further disposed on the third encapsulation layer 117c.

The buffer film 118 can prevent damage to the light emitting layer 122 of the light emitting element 120 that is vulnerable to a chemical solution or moisture and high temperature. For example, when the touch detection part is formed, a chemical solution (developing solution, etching solution, etc.) used in the process, moisture from the outside, etc., may be generated. To prevent the chemical solution, moisture. etc., from penetrating into the light emitting layer 122 containing an organic material while the touch detection part is manufactured, the buffer film 118 may be disposed, and the touch detection part may be disposed above the buffer film 118. In addition, the buffer film 118 may be formed at a predetermined temperature (e.g., at a low temperature of 100° C. or lower) and made of an organic insulating material having a low dielectric constant of 1 to 3. For example, the buffer film 118 may be made of an acrylic-based, epoxy-based, or siloxan-based material.

In addition, the buffer film 118 can prevent damage to the encapsulation part 117 and breakage of the touch electrode of the touch detection part due to the bending of the flexible display apparatus. For example, since the buffer film 118 may be made of an organic insulating material and may have planarization performance, even when the flexible display apparatus is bent, it is possible to prevent the damage to the encapsulation part 117 and the breakage of the touch electrode.

For example, the touch electrode of the touch detection part may be disposed on the buffer film 118. The touch electrode may include a touch sensor metal and a bridge metal that are positioned in different layers, and a touch interlayer insulating film may be disposed between the touch sensor metal and the bridge metal. For example, the touch sensor metal may include a first touch sensor metal, a second touch sensor metal, and a third touch sensor metal that are disposed adjacent to each other. The first touch sensor metal and the second touch sensor metal may be electrically connected, and when the third touch sensor metal is present between the first touch sensor metal and the second touch sensor metal, the first touch sensor metal and the second touch sensor metal may be electrically connected through the bridge metal positioned in a different layer. The bridge metal may be insulated from the touch sensor metal by the touch interlayer insulating film.

Meanwhile, in the display apparatus 100 according to one embodiment of the present specification, an organic layer covering the color filter part and the touch detection part may be further disposed on the encapsulation part 117. For example, an organic layer covering the touch electrode of the touch detection part may be disposed, and the organic layer may be formed of an organic insulating film.

In addition, in the display apparatus 100 according to one embodiment of the present specification, a polarization layer and a cover layer (for example, a cover glass) may be further disposed on the above-described organic layer on the encapsulation part 117.

The polarization layer can suppress the reflection of external light on the display area DA of the substrate 110. For example, when the display apparatus 100 is used externally, external natural light may be introduced and reflected by the reflective layer included in the anode electrode 121 of the light emitting element 120 or reflected by an electrode made of a metal disposed under the light emitting element 120. An image of the display apparatus 100 may be invisible due to the reflected light in this way. The polarization layer may polarize the light introduced from the outside in a specific direction and prevent the reflected light from being emitted back to the outside of the display apparatus 100.

In addition, the cover glass can protect the components of the display apparatus 100 from an external impact and prevent damage such as scratches. The cover glass may be adhered to the polarization layer by an adhesive layer. For example, the adhesive layer may be formed using an optically transparent display adhesive such as a pressure-sensitive adhesive, an optical clear adhesive (OCA), or an optical clear resin (OCR), but is not limited thereto.

The present specification has been described assuming that the display apparatus 100 is an organic light emitting display, but is not limited thereto. For example, when the display apparatus 100 is an organic light emitting display, the sub-pixel may include the light emitting element 120 including the anode electrode 121, the light emitting layer 122 on the anode electrode 121, and the cathode electrode 123 on the light emitting layer 122. In this case, the light emitting element 120 may include an organic light emitting layer as the light emitting layer 122 and further include a hole transport layer, a hole injection layer, an electron injection layer, and an electron transport layer in addition to the organic light emitting layer. Meanwhile, as another example, when the display apparatus 100 is a liquid crystal display, the display apparatus 100 may be configured to include a liquid crystal layer that is a display portion.

FIG. 4 is a plan view of a portion of the display panel according to one embodiment of the present specification.

Referring to FIG. 4, the display panel DP includes the substrate 110.

The substrate 110 is configured to support various components included in the display apparatus 100. The substrate 110 may be made of an insulating material. In addition, the substrate 110 may be made of a transparent material. In addition, the substrate 110 may be a rigid substrate or a flexible substrate capable of bending, folding, rolling, etc. In addition, the substrate 110 may be made of glass or a flexible plastic material. For example, when the substrate 110 is made of a plastic material, polyimide (PI), the manufacturing process of the display apparatus 100 may be performed in a situation in which a support substrate made of glass is disposed under the substrate 110, and the support substrate may be released after the manufacturing process of the display apparatus 100 is completed.

As shown in FIG. 4, the display panel DP may include the display area DA and the non-display area NA which is positioned outside the display area DA and in which a plurality of pixels PX are not disposed.

The non-display area NA may include a pad area PA including pads electrically connected to the display area DA. One or more flexible circuit boards 200 may be connected to the pad area PA.

One or more flexible circuit boards 200 may be attached to a portion of the pad area PA through an anisotropic conductive film (ACF) bonding. The ACF may be formed of a thermosetting epoxy resin film and a conductive ball.

Since the non-display area NA is not an area in which an image is displayed, the non-display area NA does not need to be visible from the front of the display panel DP. Therefore, a portion of the non-display area NA may be bent toward a back surface of the display panel DP, for example, may be bent toward the back surface of the display panel DP so that one edge of the substrate 110 has a predetermined curvature.

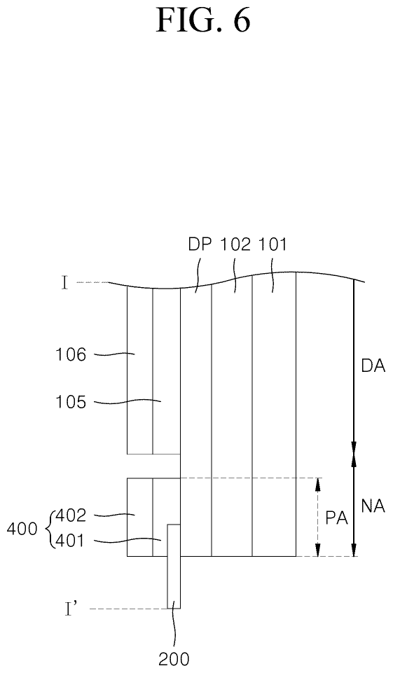

The pad area PA may have a smaller cross-sectional thickness than the display area DA. For example, a cover glass (not shown) may be further positioned on the display area DA. In this case, an optical sheet (see the second optical sheet 105 in FIG. 6) and an additional adhesive layer (see the second adhesive layer 106 in FIG. 6) may be positioned between the display area DA and the cover glass (not shown). Therefore, a component that is not positioned in the pad area PA may be additionally present on the display area DA so that the thickness of the cross-section of the display area DA is larger than that of the pad area PA, thereby protecting the display area DA and improving the quality of an image.

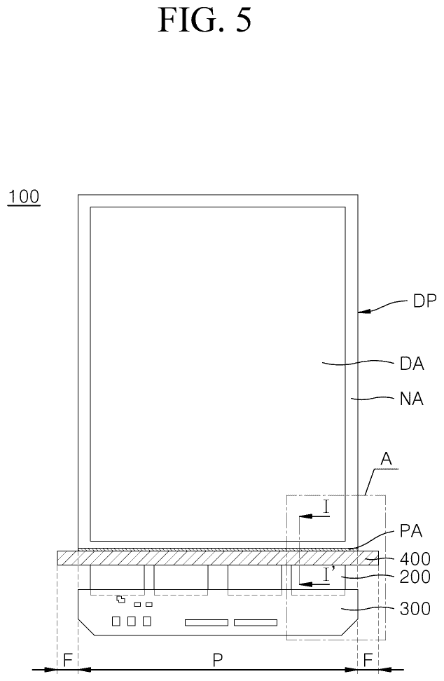

FIG. 5 is a plan view of a display panel according to one embodiment of the present specification, and the reinforcing member 400 will be described in more detail with reference to FIG. 5.

The reinforcing member 400 may be positioned to overlap a portion of the flexible circuit board 200 on the pad area PA of the display panel DP and may protrude more than both ends of the display panel DP. A printed circuit board 300 may be connected to the flexible circuit board 200.

The reinforcing member 400 may include a protection portion P and a fixing portion F.

The protection portion P may be positioned to overlap a portion of the flexible circuit board 200 on the pad area PA and may serve to protect the pad area PA. However, the present specification is not limited thereto. For example, the reinforcing member 400 may at least partially cover the pad area PA. In this case, the relatively vulnerable pad area PA of the display panel DP may be protected by the reinforcing member 400.

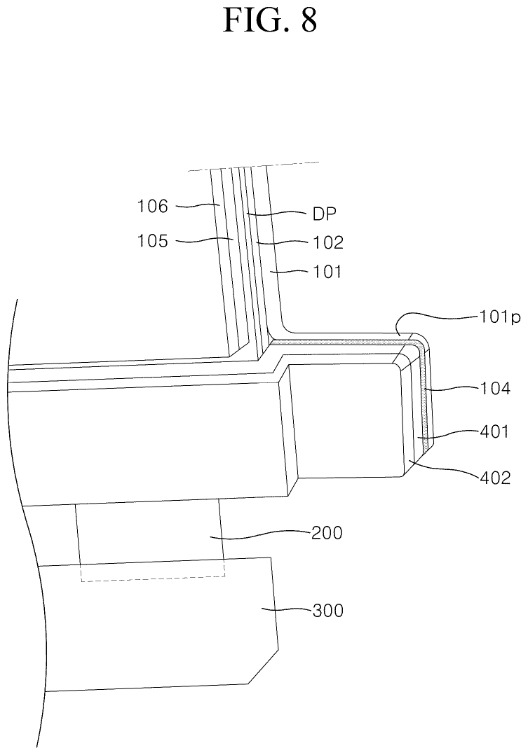

The fixing portion F may be positioned outside both ends of the display panel DP and may be adhered to a portion of a support plate 101 which would be described below, that is, a portion (see the protrusion 101p of the support plate 101 in FIG. 8) of a support plate 101 protruding outward so that the reinforcing member 400 may be fixed to the display apparatus. However, the present specification is not limited thereto. For example, the fixing portion F may extend to an end of the display panel DP from at least side of the protection portion P, and may be bent to a side surface of the display panel DP. In some embodiments, the fixing portion F may be fixed to a component of the display apparatus 100 at an end of the display panel DP or a side surface of the display panel DP. For example, the fixing portion F may be fixed to a component such as a support plate 101 at the side surface of the display panel DP through welding, adhering, snap-fit, etc.

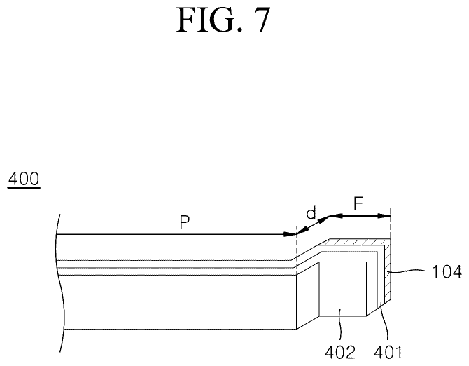

As shown in FIG. 7, the protection portion P and the fixing portion F may be positioned to have a step d, and the thickness of an area in which the fixing portion F is positioned may be smaller than the thickness of an area in which the protection portion P is positioned. Therefore, fixing strength can be reinforced by protecting the pad area PA through the protection portion P and minimizing components to be supported by the fixing portion F. In addition, it is possible to reduce the cost and increase productivity by changing only a shape of the support plate 101.

The reinforcing member 400 may be formed of a first layer 401 and a second layer 402.

The first layer 401 and the second layer 402 may be made of different materials, and the first layer 401 may be made of a soft material to protect the pad area PA, and the second layer 402 may be made of a hard material to prevent an external impact.

Therefore, the first layer 401 may be made of a urethane material, and the second layer 402 may be made of a metal material, but the present specification is not limited thereto.

Although not shown in the drawing, the fixing portion F of the reinforcing member 400 may be used as a protrusion that may be fastened to a component of a set product (not shown) and may have a shape that is bent to the back surface of the display panel DP or bent at a right angle depending on a shape of a coupling portion in the component of the set product (not shown).

Therefore, the display apparatus according to one embodiment of the present specification may be more firmly fastened to the component of the set product.

In addition, the relatively vulnerable pad area PA of the display panel DP may be designed more robustly by the reinforcing member 400 of the display panel DP, thereby protecting the display panel DP from an external impact.

In addition, it is possible to reduce the shrinkage and expansion of the display panel DP in a high-temperature and high-humidity environment, thereby preventing damage to the display panel DP.

FIG. 6 is a cross-sectional view along line I-I′ in FIG. 5.

A lower surface of the display panel DP may further include the support plate 101 and a back plate 102.

The support plate 101 may be made of an aluminum material, but is not limited thereto.

The back plate 102 may be positioned between the support plate 101 and the display panel DP.

In the display panel according to one embodiment of the present specification, the reinforcing member 400 may be positioned to overlap a portion of the flexible circuit board 200 on the pad area PA. The first layer 401 of the reinforcing member 400 may be made of a soft material, such as a urethane material, which may protect the pad area PA.

In addition, one or more flexible circuit boards 200 may be attached to a portion of the pad area PA through ACF bonding, and the ACF may include very fine conductive balls.

Therefore, even when the reinforcing member 400 is positioned to overlap a portion of the flexible circuit board 200, the reinforcing member 400 may not greatly affect a height of the first layer 401.

The reinforcing member 400 of the pad area PA may be positioned parallel to a second adhesive layer 106 of the display area DA in a plan view. Furthermore, a height of an upper surface of the protection portion P of the reinforcing member 400 may be the same as a height of an upper surface of the second adhesive layer 106. Therefore, the reinforcing member 400 may be coupled without any gap even when assembled with a component of a set product, and the reinforcing member 400 may protect the pad area PA to prevent defects of the display panel caused by an external impact.

In addition, the reinforcing member 400 may press the pad area PA to prevent a change in shrinkage and expansion of the display panel in a high-temperature and high-humidity environment. For example, the first layer 401 of the reinforcing member 400 may be made of a material which is softer than the second layer 402. In this case, when the reinforcing member 400 is mounted, the first layer 401 may contact the pad area, thereby the first layer may be compressed to press the pad area PA.

Hereinafter, the form of the reinforcing member of the display apparatus 100 according to one embodiment of the present specification and the structure applied to the display apparatus will be described in detail with reference to FIGS. 7 and 8.

As described in FIG. 7, the reinforcing member 400 may be formed so that the protection portion P and the fixing portion F have the step d.

The display apparatus 100 according to one embodiment of the present specification may further include the support plate 101 on the back surface of the display panel DP, and the support plate 101 may include a protrusion 101p overlapping the fixing portion F of the reinforcing member 400.

The first adhesive layer 104 is positioned between the support plate 101 and the fixing portion F of the reinforcing member 400, specifically, between the protrusion 101p of the support plate 101 and the fixing portion F of the reinforcing member 400, and thus the reinforcing member 400 is coupled to the display apparatus.

The support plate 101 and the reinforcing member 400 may be made of aluminum (Al), stainless steel (SUS), etc., but are not limited thereto, and may be made of a material having high rigidity and a thin shape, and having little deformation due to temperature and humidity.

Referring to FIG. 8, the first adhesive layer 104 may be formed to have the same size as the fixing portion F, but is not limited thereto, and may be formed to have a smaller size than the fixing portion F.

The reinforcing member 400 includes the first layer 401 and the second layer 402, and at least a portion of the second layer 402 protruding to both sides of the display panel DP is positioned on the same layer as the back plate 102. In this way, the display apparatus 100 according to one embodiment of the present specification is formed so that the thickness of the fixing portion F is formed to be smaller than the thickness of the protection portion P of the reinforcing member 400 to simplify components to be fixed by the first adhesive layer 104 positioned on the fixing portion F, thereby designing a more solid display apparatus that has increased fixing strength. For example, the thickness of the second layer 402 of the fixing portion F may be formed to be smaller than the thickness of the second layer 402 of the protection portion P, or the thickness of the first layer 401 of the fixing portion F may be formed to be smaller than the thickness of the first layer 401 of the protection portion P. In addition, at least a portion of the second layer 402 of the fixing portion F may be formed to be positioned on the same layer as the back plate 102, and thus assembled without a change in thickness of a component of a set product even when coupled to the component of the set product.

Furthermore, a cover glass (not shown) may be further positioned on the display area DA. In this case, an optical sheet 105 and a second adhesive layer 106 may be positioned between the display area DA and the cover glass (not shown). The optical sheet 105 may have a function of complementing the performance of the display panel DP, and the second adhesive layer 106 may serve to attach the cover glass (not shown) on the display area DA.

The reinforcing member 400 may be positioned to be spaced apart from the optical sheet 105 and the second adhesive layer 106 and positioned to be spaced apart from the cover glass (not shown), but may not be positioned to be spaced apart at the same time. For example, even when the reinforcing member 400 is positioned to be spaced apart from the optical sheet 105 and the second adhesive layer 106, the reinforcing member 400 may be positioned to overlap the cover glass (not shown).

In a cross-section view, the reinforcing member 400 may be positioned at the same height as the second adhesive layer 106. Therefore, the display panel DP can be protected from an external impact by reinforcing the pad area PA, and a change in shrinkage and expansion in a high-temperature and high-humidity environment can be reduced.

Display apparatuses according to various embodiments of the present specification may be described as follows.

The display apparatus according to one embodiment of the present specification may include a display panel including a display area and a non-display area outside the display area, a pad area disposed in the non-display area of the display panel and including pads electrically connected to the display area, one or more flexible circuit boards connected to the pad area, and a reinforcing member overlapping the pad area and a portion of the flexible circuit board, wherein the reinforcing member may protrude more than both ends of the display panel.

The reinforcing member may be formed of a first layer and a second layer, and the first layer and the second layer may be made of different materials.

The first layer of the reinforcing member may be made of a urethane material, and the second layer may be made of a metallic material.

The reinforcing member may include a protection portion and a fixing portion, the protection portion may cover the pad area and a portion of the flexible circuit board, and the fixing portion may be positioned outside both ends of the display panel.

The reinforcing member may have a step between the protection portion and the fixing portion, and a thickness of an area in which the fixing portion is positioned of the reinforcing member may be smaller than a thickness of an area in which the protection portion is positioned of the reinforcing member.

A display apparatus according to another embodiment of the present specification may further include a support plate disposed on a back surface of the display panel, wherein the support plate may include a protrusion overlapping the fixing portion, and a first adhesive layer may be positioned between the protrusion of the support plate and the fixing portion.

In addition, the support plate and a back plate may be positioned under the display panel, and the back plate may be positioned between the support plate and the display panel. The reinforcing member may include a first layer and a second layer, and at least a portion of the second layer protruding to both sides of the display panel may be positioned on the same layer as the back plate.

An optical sheet and a second adhesive layer may be positioned on the display panel.

The reinforcing member may be positioned parallel to the second adhesive layer in a plan view.

A cover glass may be positioned on the second adhesive layer.

The reinforcing member may be positioned to be spaced apart from the optical sheet and the second adhesive layer.

The reinforcing member may be positioned to be spaced apart from the cover glass.

A cover glass may be positioned on the second adhesive layer, and the reinforcing member may be positioned to overlap the cover glass.

The first layer may be made of a material which is softer than the second layer, and the first layer may contact the pad area.

The first layer may be compressed to press the pad area.

The fixing portion may have a shape that is bent to a back surface of the display panel or bent at a right angle.

The reinforcing member may include a protection portion covering the pad area, and a height of an upper surface of the protection portion may be the same as a height of an upper surface of the second adhesive layer.

The display apparatus according to another embodiment of the present specification may include a display panel including a display area and a non-display area outside the display area, a pad area disposed in the non-display area of the display panel and including pads electrically connected to the display area, and a reinforcing member at least partially covering the pad area.

The reinforcing member may include a protection portion and a fixing portion, the protection portion may at least partially cover the pad area, and the fixing portion may extend to an end of the display panel from at least side of the protection portion, and be bent to a side surface of the display panel.

The fixing portion may be fixed to a support plate disposed on a back surface of the display panel at the side surface of the display panel.

The display apparatus according to one embodiment of the present specification can prevent the defect of the display panel caused by an external impact by including one or more flexible circuit boards connected to the pad area of the display panel and including the reinforcing member overlapping the pad area and a portion of the flexible circuit board.

The display apparatus according to one embodiment of the present specification can prevent damage to the panel by reducing a change in shrinkage and expansion of the display panel in the high-temperature and high-humidity environment.

The display apparatus according to one embodiment of the present specification can maximize the environmental, social, and governance (ESG) effect such as reducing production energy by preventing the above problems, and reducing power consumption through the improvement in performance such as high efficiency/long lifetime.

The effects according to the embodiments of the present specification are not limited by the above-described exemplary contents, and various further effects are included in the present specification.

Although the embodiments of the present specification have been described in more detail with reference to the accompanying drawings, the present specification is not necessarily limited to these embodiments, and various modifications may be carried out without departing from the technical spirit of the present specification. Therefore, the embodiments disclosed in the present specification are not intended to limit the technical spirit of the present specification, but is intended to describe the same, and the scope of the technical spirit of the present specification is not limited by these embodiments. Therefore, it should be understood that the above-described embodiments are illustrative and not restrictive in all aspects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a display panel including a display area and a non-display area adjacent to the display area;
a pad area disposed in the non-display area of the display panel, the pad area including pads electrically connected to the display area;
one or more flexible circuit boards electrically connected to the pad area; and
a reinforcing member overlapping the pad area and a portion of a flexible circuit board among the one or more flexible circuit boards,
wherein the reinforcing member protrudes more than both ends of the display panel.

2. The display apparatus of claim 1, wherein the reinforcing member includes a first layer and a second layer, and
wherein the first layer and the second layer include different materials.

3. The display apparatus of claim 2, wherein the first layer of the reinforcing member is made of a urethane material, and the second layer of the reinforcing member is made of a metal material.

4. The display apparatus of claim 1, wherein the reinforcing member includes a protection portion and a fixing portion,
wherein the protection portion covers the pad area and a portion of the flexible circuit board, and
wherein the fixing portion is positioned outside the both ends of the display panel.

5. The display apparatus of claim 4, further comprising a support plate on a back surface of the display panel,
wherein the support plate includes a protrusion overlapping the fixing portion.

6. The display apparatus of claim 5, wherein a first adhesive layer is between the protrusion of the support plate and the fixing portion.

7. The display apparatus of claim 4, wherein the reinforcing member has a step between the protection portion and the fixing portion.

8. The display apparatus of claim 7, wherein a thickness of an area in which the fixing portion is positioned of the reinforcing member is smaller than a thickness of an area in which the protection portion is positioned of the reinforcing member.

9. The display apparatus of claim 1, wherein a support plate and a back plate are under the display panel, and the back plate is between the support plate and the display panel.

10. The display apparatus of claim 9, wherein the reinforcing member includes a first layer and a second layer, and
wherein at least a portion of the second layer protruding to both sides of the display panel is on a same layer as the back plate.

11. The display apparatus of claim 1, wherein an optical sheet and a second adhesive layer are on the display panel.

12. The display apparatus of claim 11, wherein the reinforcing member is parallel to the second adhesive layer in a plan view.

13. The display apparatus of claim 11, wherein a cover glass is on the second adhesive layer.

14. The display apparatus of claim 11, wherein the reinforcing member is spaced apart from the optical sheet and the second adhesive layer.

15. The display apparatus of claim 13, wherein the reinforcing member is spaced apart from the cover glass.

16. The display apparatus of claim 14, wherein a cover glass is on the second adhesive layer, and
wherein the reinforcing member overlaps the cover glass.

17. The display apparatus of claim 2, wherein the first layer is made of a material which is softer than the second layer, and
wherein the first layer contacts the pad area.

18. The display apparatus of claim 17, wherein the first layer is compressed to press the pad area.

19. The display apparatus of claim 4, wherein the fixing portion has a shape that is either bent to a back surface of the display panel or bent at a right angle.

20. The display apparatus of claim 12, wherein the reinforcing member includes a protection portion covering the pad area, and
wherein a height of an upper surface of the protection portion is the same as a height of an upper surface of the second adhesive layer.

21. A display apparatus comprising:
a display panel including a display area and a non-display area adjacent to the display area;
a pad area disposed in the non-display area of the display panel, the pad area including pads electrically connected to the display area; and
a reinforcing member at least partially covering the pad area.

22. The display apparatus of claim 21, wherein the reinforcing member includes a protection portion and a fixing portion,
wherein the protection portion at least partially covers the pad area, and
wherein the fixing portion extends to an end of the display panel from at least side of the protection portion, and is bent to a side surface of the display panel.

23. The display apparatus of claim 22, wherein the fixing portion is fixed to a support plate disposed on a back surface of the display panel at the side surface of the display panel.
